(19) United States
(12) Patent Application Publication
(10) Pub. No.: US 2015/0261446 A1
(43) Pub. Date: Sep. 17, 2015

(54) DDR4-ONFI SSD 1-TO-N BUS ADAPTATION AND EXPANSION CONTROLLER

(71) Applicant: Futurewei Technologies, Inc., Plano, TX (US)

(72) Inventor: Xiaobing LEE, Santa Clara, CA (US)

(21) Appl. No.: 14/656,451

(22) Filed: Mar. 12, 2015

Related U.S. Application Data
(60) Provisional application No. 61/951,987, filed on Mar. 12, 2014.

(51) Int. Cl. G06F 3/06; G11C 7/10

(52) U.S. Cl. CPC G06F 3/0608; G06F 3/0688; G11C 7/1075; G06F 3/0661; G06F 3/061

(57) ABSTRACT

An apparatus for communicating data requests received by host devices using one DDR protocol to memory devices using a different DDR protocol is presented. The apparatus includes an ONFI communication interface is for communicating with a plurality of flash memory devices and a SSD processor coupled to the communication interface. The SSD processor receives a first signal from a host device corresponding to a first DDR protocol to access DRAM, stores the first signal upon receipt in a data buffer of a plurality of data buffers resident on the apparatus, converts the first signal into a second signal using an ONFI standard, transmits the configured second signal to one of the plurality of flash memory devices corresponding to a second DDR protocol, and receives data from the flash memory device, where the data is converted into signals corresponding to the first DDR4 protocol for communication back to the host device.

### CROSS-REFERENCE TO RELATED APPLICATIONS

This application claims priority from U.S. Provisional Patent Application Ser. No. 61/951,987, filed Mar. 12, 2014 to Lee et al., entitled “DDR4 BUS ADAPTION CIRCUITS TO EXPAND ONFI BUS SCALE-OUT CAPACITY AND PERFORMANCE” which is incorporated herein by reference in its entirety.

### FIELD OF THE INVENTION

The present invention generally relates to the field of random access memory (RAM). More specifically, the present invention is related to a DDR4-SSD dual-port DIMM with a DDR4 bus adaptation circuit configured to expand scale-out capacity and performance.

### BACKGROUND OF THE INVENTION

DDR4 and NVM technologies have been developed as single port memory modules directly attached to CPUs. DDR4 provides the multi-channel architecture of point-to-point connections for CPUs hosting more high-speed DDR4-DIMMs (dual-port dual in-line memory module) rather than previous multi-drop DDR2/3 bus technologies, resulting in more DIMMs having to sacrifice bus-speed. However, the technology has yet to be widely adopted. So far, the vast majority of DDR4 motherboards are still using old multi-drop bus topology.

High density, all-flash-arrays (AFA) storage systems or large-scale NVM systems must use dual-port primary storage modules similar as the SAS-HDD devices for higher reliability and availability (e.g., avoiding single-point failures in any data-paths). The higher the SSD/NVM density is, the more critical the primary SSD/NVM device will be. For example, a high-density DDR4-SSD DIMM may have 15 TB to 20 TB storage capacity. Also, conventional NVDIMMs are focused on maximizing DRAM capacity with the same amount of Flash NAND for power-down protection as persistent-DRAM. Furthermore, conventional UltraDIMM SSD units use a DDR3-SATA controller plus 2 SATA-SSD controllers and 8 NAND flash chips to build SSDs in DIMM form factor with the throughput less than 10% of DDR3 bus bandwidth.

### SUMMARY OF THE INVENTION

Accordingly, embodiments of the present invention provide a novel approach to put high density AFA primary storage in DDR4 bus slots. Embodiments of the present invention provide DDR4-SSD DIMM form factor designs for high-density storage, without bus speed and utilization penalties, in high ONFI memory chip loads that can be directly inserted into a DDR4 motherboard. Moreover, embodiments of the present invention provide a novel 1:2 DDR4-to-ONFI NV-DDR2 signaling levels, terminations/relaying, and data-rate adaption architecture design.

As such, embodiments can gang up N of 1:2 DDR4-ONFI adaptors to form N times ONFI channel expressions to scale out flash NAND storage. Also, embodiments introduce DDR4 1:2 data buffer load-reducing technologies that can make N=10 or 16 higher fan-outs in the DDR4 domain. In this fashion, NV-DDR2 channel load expansions can occur with lower speed loss or higher bus utilizations. Furthermore, embodiments also include a plurality of DDR4-DRAM chips (e.g., 32 bits) for data buffering, FTL tables or KV tables, GC/WL tables, control functions, and 1 DDR3-STTRAM chip for write caching and power-down protections.

Embodiments of the present invention include DDR4-DIMM interface circuits and DDR4-SDRAM to buffer high speed DDR4 data flows. Embodiments include DDR4-ONFI controllers configured for ONFI-over-DDR4 adaptions, FTL controls, FTL-metadata managements, ECC controls, GC and WL controls, I/O command queuing. Embodiments of the present invention enable 1-to-2 DDR4-to-ONFI NV-DDR2 bus adaptations/terminations/relays as well as data buffering and/or splitting. Furthermore, embodiments of the present invention provide 1-to-N DDR4-ONFI bus expansion methods.

### BRIEF DESCRIPTION OF THE DRAWINGS

The accompanying drawings, which are incorporated in and form a part of this specification, illustrate embodiments of the invention and, together with the description, serve to explain the principles of the invention:

FIG. 1 is a block diagram of an exemplary DDR4-SSD dual-port DIMM configuration in accordance with embodiments of the present invention.

FIG. 2 depicts an exemplary DDR4-SSD Controller on the dual-port DIMM unit in accordance with embodiments of the present invention.

FIG. 3 is a block diagram illustrating an exemplary DDR4-ONFI Adapter in accordance with embodiments of the present invention.

FIG. 4A is a block diagram of an exemplary packed 3-PCB DIMM device scaled up by three hard-connected printed circuit boards in accordance with embodiments of the present invention.

FIG. 4B is a block diagram of an exemplary packed 5-PCB DIMM device scaled up by five connected printed circuit boards scaled up in accordance with embodiments of the present invention.

FIG. 5 is a block diagram depicting an exemplary DDR4-SSD dual-port DIMM and SSD Controller configuration scaled up by three connected printed circuit boards in accordance with embodiments of the present invention.

FIG. 6 is a block diagram of an exemplary DDR4-SSD Controller adapted to scale up multiple printed circuit boards in accordance with embodiments of the present invention.

FIG. 7 is a block diagram of a DDR4-SSD dual-port DIMM configured for mixing with DDR4-DRAM and DDR4-NVM in conventional CPUs memory bus (as single-port DIMM unit) in accordance with embodiments of the present invention.

FIG. 8 is a block diagram of a DDR4-DDR3 speed-doublers configuration in accordance with embodiments of the present invention.

FIG. 9 depicts a network storage node topology for network storage in accordance with embodiments of the present invention.

FIG. 10A is a block diagram of an exemplary DDR4-SSD dual-port DIMM configuration supporting multiple PCBs (packed 3-PCB) DIMM devices in accordance with embodiments of the present invention.

FIG. 10B is another block diagram of an exemplary DDR4-SSD dual-port DIMM configuration supporting multiple PCBs (packed 5-PCB) devices in accordance with embodiments of the present invention.

FIG. 11A is a flowchart of a first portion of an exemplary computer-implemented method for performing data access request in a network storage system in accordance with embodiments of the present invention.

FIG. 11B is a flowchart of a second portion of an exemplary computer-implemented method for performing data access request in a network storage system in accordance with embodiments of the present invention.

### DETAILED DESCRIPTION

Reference will now be made in detail to several embodiments. While the subject matter will be described in conjunction with the alternative embodiments, it will be understood that they are not intended to limit the claimed subject matter to these embodiments. On the contrary, the claimed subject matter is intended to cover alternative, modifications, and equivalents, which may be included within the spirit and scope of the claimed subject matter as defined by the appended claims.

Furthermore, in the following detailed description, numerous specific details are set forth in order to provide a thorough understanding of the claimed subject matter. However, it will be recognized by one skilled in the art that embodiments may be practiced without these specific details or with equivalents thereof. In other instances, well-known methods, procedures, components, and circuits have not been described in detail as not to unnecessarily obscure aspects and features of the subject matter.

Portions of the detailed description that follows are presented and discussed in terms of a method. Embodiments are well suited to performing various other steps or variations of the steps recited in the flowchart of the figures herein, and in a sequence other than that depicted and described herein.

Some portions of the detailed description are presented in terms of procedures, steps, logic blocks, processing, and other symbolic representations of operations on data bits that can be performed on computer memory. These descriptions and representations are the means used by those skilled in the data processing arts to most effectively convey the substance of their work to others skilled in the art. A procedure, computer-executed step, logic block, process, etc., is here, and generally, conceived to be a self-consistent sequence of steps or instructions leading to a desired result. The steps are those requiring physical manipulations of physical quantities. Usually, though not necessarily, these quantities take the form of electrical or magnetic signals capable of being stored, transferred, combined, compared, and otherwise manipulated in a computing device. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the following discussions, it is appreciated that throughout, discussions utilizing terms such as “accessing,” “writing,” “including,” “storing,” “transmitting,” “reading,” “associating,” “identifying” or the like, refer to the action and processes of an electronic computing device that manipulates and transforms data represented as physical (electronic) quantities within the system's registers and memories into other data similarly represented as physical quantities within the system memories or registers or other such information storage, transmission or display devices.

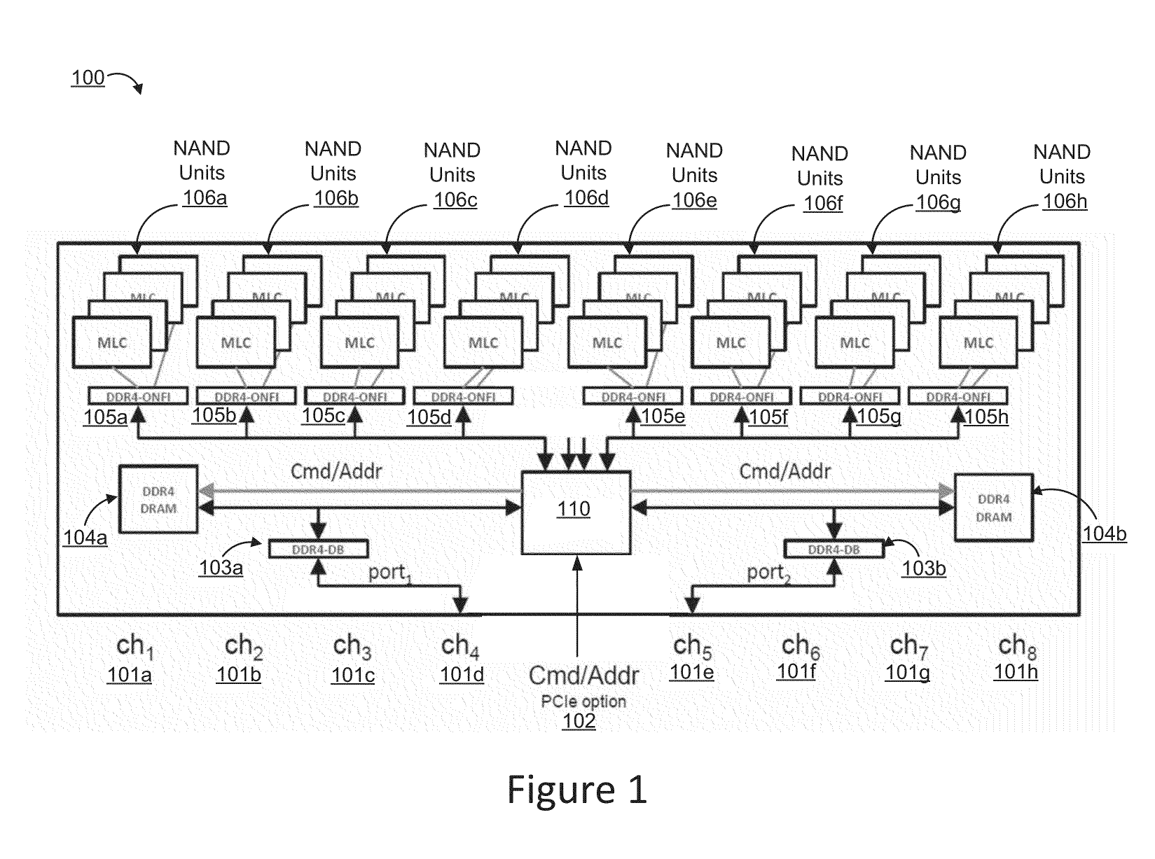

FIG. 1 is a block diagram of an exemplary DDR4-SSD dual-port DIMM configuration in accordance with embodiments of the present invention. As illustrated in FIG. 1, DIMM device 100 includes a dual-port DDR4-Solid State Drive (SSD) controller or processor (e.g., DDR4-SSD Controller 110). DDR4-SSD Controller 110 includes the functionality to receive DDR4 control bus signals and data bus signals. For example, the DDR4-SSD Controller 110 can receive control signals 102 (e.g., single data rate signals) over a DDR4-DRAM command/address bus (optional NVME/PCIE-port).

DDR4-SSD Controller 110 can receive control signals and/or data streams via several different channels capable of providing connectivity by CPUs to a network comprising a pool of network resources. The pool of resources may include, but is not limited to, virtual machines, CPU resources, non-volatile memory pools (e.g., flash memory), HDD storage pools, etc. As depicted in FIG. 1, DDR4-SSD Controller 110 can receive control signals 102 and from a pre-assigned channel or a set of pre-assigned channels (e.g., channels 101d and 101e). For example, channels 101d and 101e can be configured as 8-bit ports (e.g., “port 1” and “port 2”, respectively) which enable multiple different host devices (e.g., CPUs) to access data buffered in DDR4 DRAM 104a and 104b.

DDR4-DBs 103a and 103b can be data buffers which serve as termination/multiplex for DDR4 bus to be shared by host CPUs and DDR4-SSD controller. In this fashion, DDR4-DBs 103a and 103b includes the functionality to manage the loads of external devices such that DDR4-DBs 103a and 103b can drive signals received through channels 101d and 101e to other portions of the DDR4-SSD controller 110 (e.g., DDR4 DRAM 104a, 104b, NAND units 106a through 106h, etc.).

As depicted in FIG. 1, DDR4 DRAM 104a and 104b can be accessed by DDR4-SSD Controller 110 and/or accessed by a CPU or multiple CPUs through port1 101d and port1 101e then thru DDR4-DBs 103a and 103b. DDR4 DRAM 104a and 104b enables host CPUs to map them into virtual memory space for a particular resource or I/O device. As such, other host devices and/or other devices can perform DMA and/or RDMA read and/or write data procedures using DDR4 DRAM 104a and/or 104b. In this fashion, DDR4 DRAM 104a and 104b act as dual port memory for DDR4-SSD Controller and CPUs. DIMM device 100 can utilize two paths that can use active-passive (“standby”) or active-active modes to increase the reliability and availability of storage systems on DIMM device 100.

For instance, if multiple host devices seek to perform procedures involving DDR4 DRAM (e.g., read and/or write procedures), SSD Controller 110 can determine whether a particular DDR4 DRAM (e.g., DDR4 DRAM 104a) is experiencing higher latency than another DDR4 DRAM (e.g., DDR4 DRAM 104b). Thus, when responding to a host device's request to perform the procedure, SSD Controller 110 can communicate the instructions sent by the requesting host device to the DDR4 DRAM that is available to perform the requested procedure where it can then be stored for processing. In this manner, DDR4 DRAM 104a and 104b act as separate elastic buffers that are capable of performing DDR4-to-DDR2 rate reduction procedures with buffer data received. This allows for a transmission rate (e.g., 2667 MBs host rate) for host and eAsic bus masters to perform “ping pang” access.

Also, as depicted in FIG. 1, DIMM device 100 also includes a set of DDR4-ONFI adapters (e.g., DDR4-ONFI adapters 105a through 105h) which can each receive signals from SSD Controller 110 to control operation of a plurality of 64 MLC+(multi layer cell) NAND chips (e.g., NAND units 106a through 106h). NAND units can include technologies such as SLC, MLC, TLC, etc.

As such, SSD Controller 110 can transform control bus signals and/or data bus signals in accordance with current ONFI communications standards. Moreover, SSD Controller 110 can communicate with a particular ONFI adapter using a respective DDR4 channel programmed for the ONFI adapter. In this fashion, DIMM device 100 enables communications between different DIMM components operating on different DDR standards. For example, NAND chips operating under a particular DDR (e.g., DDR1, DDR2, etc.) technology can send and/or receive data from DRAMs using DDR4 technology.

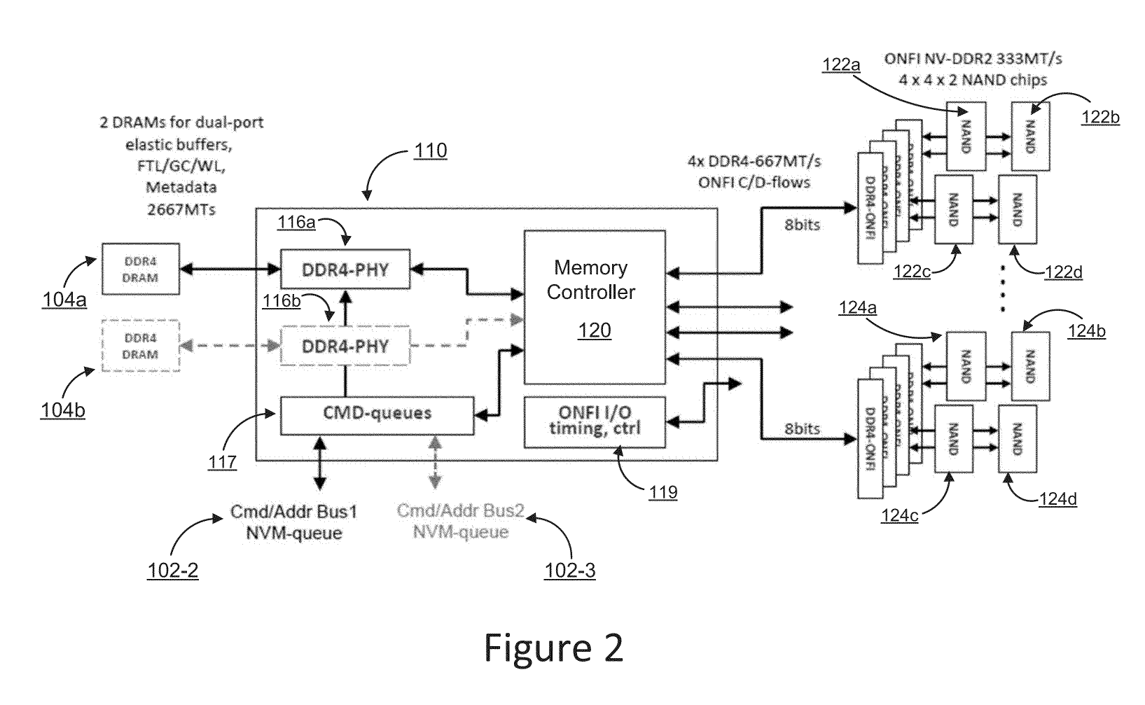

FIG. 2 depicts an exemplary SSD Controller 110 in accordance with embodiments of the present invention. As illustrated in FIG. 2, SSD Controller 110 can enable read/write access procedures concerning DDR4-DRAM 104a and 104b with controls from multiple CPUs through multiple Cmd/Addr bus signals (e.g., signals 102-2, 102-3). For instance, Cmd/Addr buses 102-2 and 102-3 can be two 8 bit ONFI Cmd/Addr channels by splitting the conventional DDR4-DIMM Cmd/Addr bus. Controls and NVME commands are cached in CMD queue 117 then saved to DDR4-DRAM 104a or 104b where they can wait to be executed. For example, bus 102-2 can receive commands from one CPU and bus 102-3 can receive commands from a different CPU. As such, SSD Controller 110 can process sequences of stored commands (e.g., commands to burst access DDR4-DRAM and to access NAND flash pages) received from CPUs.

For example, a CPU can write commands thru bus 102-2 which includes instructions to write data to DDR4-DRAM. SSD Controller 110 stores the instruction within DDR4-DRAM 104a or 104b upon DRAM traffic conditions. Upon NVME write commands, SSD Controller 110 can allocate the input buffers in DRAM 104a and associated flash page among NAND flash chip arrays 122a/b through 124a/b. Thereafter, an ONFI-over-DDR4 write sequences can be carried out thru bus 102-2 with Cmd/Addr and thru port1 101d then DDR4-DB 103a with the data bursts written into pre-allocated buffers in DDR4-DRAM 104a synchronously. Moreover, NVME commands will be inserted to each 8 or 16 DIMMs 100 thru bus 102 concurrently.

Memory Controller 120 will generate sequences of Cmd/Address signals of BL8 writes or reads to perform long burst access to DDR4 DRAM 104a and 104b (16 KB write page or 4 KB read page) under CPUs controls. Memory controller 120 includes the functionality to retrieve data from a particular NAND chip as well as a DDR4-DRAM based on signals received by SSD Controller 110 from a host device. In one embodiment, memory controller 120 includes the functionality to perform ONFI-over-DDR4 adaptions, FTL controls, FTL-metadata managements, EEC controls, GC and WL controls, I/O command queuing, etc. Host device signals can include instructions capable of being processed by memory controller 120 to place data in DDR4-DRAM for further processing. As such, memory controller 120 can perform bus adaption procedures which include interpreting random access instructions (e.g., instructions concerning DDR4-DRAM procedures) as well as page (or block) access instructions (e.g., instruction concerning NAND processing procedures). As illustrated in FIG. 2, memory controller 120 can establish multiple channels of communications between a set of different NAND chips (e.g., NAND chips 122a-122d and 124a-124d) through their corresponding DDR4-ONFI adapters (e.g., DDR4-ONFI adapters 105a through 105h). For instance, each channel of communication can transmit 8 bits of data which can drive 4 different DDR4-ONFI adapters. In this fashion, a DDR4-ONFI adapter can drive at least two NAND chips.

Memory controller 120 can also include decoders which assist memory controller 120 in decoding instructions sent from a host device. For instance, decoders can be used by memory controller 120 to determine NAND addresses and/or the location of data stored in DDR4-DRAM 104a and 104b when performing an operation specified by a host device. DDR4-PHY 116a and 116b depict application interfaces which enable communications between memory controller 120 and DDR4-DRAM 104a and 104b and/or CMD queues 117. Memory controller 120 also includes the functionality to periodically poll processes occurring within a set of NAND units (e.g., NAND chips 122a-122d and 124a-124d) in order to assess when data can be made ready for communication to a DDR4-DRAM for further processing.

Furthermore, memory controller 120 includes the functionality communicate output back to a host device (e.g., via CMD-queues 117) using the address of the host device. ONFI I/O timing controller 119 includes the functionality to perform load balancing. For instance, if a host device sends instructions to write data to DDR4-DRAM, ONFI I/O timing controller 119 can assess latency with respect to NAND processing and report status data to memory controller 120 (e.g., using a table). Using this information, memory controller 120 can optimize and/or prioritize the performance of read and/or write procedures specified by host devices.

Moreover, as described herein, embodiments of the present invention utilize “active-passive” dual-access modes of DDR4-SSD DIMM. In one embodiment, only 1 port is used in the active-passive dual-access mode. Also, in one embodiment, 1 byte can be used in the dual-access mode. As depicted in FIG. 2, one port can be placed in “stand by” for fall-over access to NAND units (depicted as dashed lines). Thus, in an “active-active” dual-access mode, 2 DDR4 ports could be used to maximize DDR4-SSD DIMM I/O bandwidth. In this fashion, each DDR4-DRAM can be 50% used by host devices and 50% can be used by an SSD controller and/or ONFI adapter. Furthermore, in one embodiment, 2 DDR4-SSD DIMM can be paired for 1-channel to maximize host 8 bit-channel throughput as 50% for a first DDR4-SSD DIMM and 50% for second DIMM accesses. Thus, a host device configured for 8 DDR4 channels can support 16 DDR4-SSD DIMMS in which each DDR4 can expand to 64 MCL+NAND units (chips).

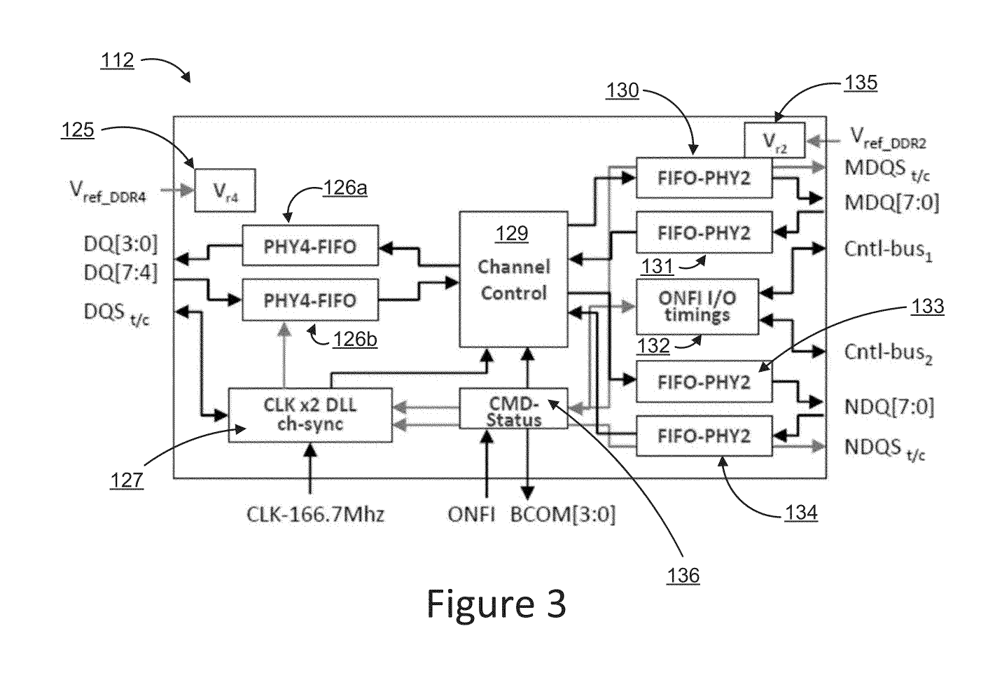

FIG. 3 is a block diagram illustrating an exemplary DDR-ONFI Adapter in accordance with embodiments of the present invention. In one embodiment, DDR4-ONFI adapter 112 can be a DDDR4-ONFI 1:2 adaptors with DDR4-PHYs at the high-speed side (e.g., PHY4-FIFO 126a, 126b) and DDR2-PHY (e.g., FIFO-PHY2 130, 131, 133, 134) at the NV-DDR2 side. In this fashion, DDR4-ONFI adapter 112 can have enough FIFOs for smooth rate-doubling. Also, DDR4-ONFI adapter 112 can include a CLK-DLL 127 to synchronize DQS and DQS_M/N data-strobe pairs for proper timing and phase and 2 Vrefs (e.g., Vref 125 and 135) for DDR4 and DDR2 reference levels and terminations.

Channel control 129 includes the functionality to optimize and/or prioritize the performance of communications between data passed between NAND chips and memory controller 120. For example, channel control 129 can prioritize the transmission of data between NAND chips and memory controller 120 based on the size of the data to be carried and/or whether the operation concerns a read and/or write command specified by a host device. Channel control 129 also includes the functionality to synchronize the transmissions of read and/or write command communications with polling procedures which can optimize the speed in which data can be processed by DIMM device 100. Moreover, unified memory interface CPUs can also accept interrupts sent from the 8 bit Cmd/Addr buses 102-2 or 102-3.

DDR4-ONFI adapter 112 can receive command signals in the form of BCOM[3:0] and/or ONFI I/O control signals. In one embodiment, these command signals may be used to control MLC+chips with in accordance with the latest JESD79-4 DDR4 data-buffer specifications. BCOM[3:0] signals 136 can control ONFI read and write timings as well as the control-pins to 4 chips using MDQ[7:0] and NDQ[7:0] channels and/or bus communication signals (e.g., signals 102-2, 102-3 shown in FIG. 2). Furthermore, it should be appreciated that data transmitted as output by DDR4-ONFI adapter 112 and received as input by NAND chips can be formatted in accordance with the latest ONFI communication standards.

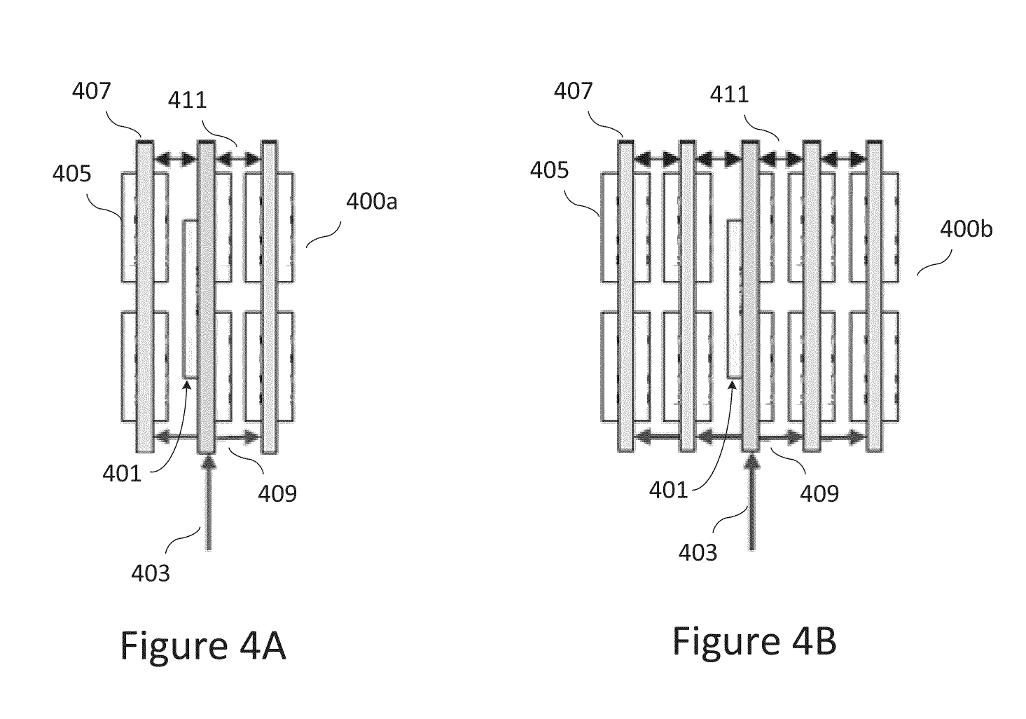

FIG. 4A depicts a block diagram of an exemplary DIMM device (e.g., device 400a) scaled up by three connected printed circuit boards as packed 3-PCB DIMM in accordance with embodiments of the present invention. As depicted in FIG. 4A, each side of the three printed circuit boards may comprise multiple memory chips 405, such as, but not exclusive to, multi-level cell NAND flash memory chips described herein. As depicted in FIG. 4A, an SSD controller 401 (e.g., similar to SSD Controller 110) is provided to adapt DDR4 instructions received via input channel 403 to a protocol compatible with the memory chips 405, such as DDR ONFI compliant protocols. Data accesses may be provided via one or more buses interconnecting the printed circuit boards 407. In an embodiment, the buses 411 may be provided at or near the top of the printed circuit boards 407. Power and a ground outlet may be provided at or near the bottom of the printed circuit boards 409.

FIG. 4B depicts a block diagram of another exemplary DIMM device (e.g., device 400b) scaled up by five connected printed circuit boards scaled up as packed 5-PCB DIMM in accordance with embodiments of the present invention. As depicted in FIG. 4B, each side of the five printed circuit boards may comprise multiple memory chips 405, such as, but not exclusive to, multi-level cell NAND flash memory chips described elsewhere in this description. An SSD controller 401 (e.g., similar to SSD Controller 110) is provided to adapt DDR4 instructions received via input channel 403 to a protocol compatible with the memory chips 405, such as DDR ONFI compliant protocols. Data accesses may be provided via one or more buses interconnecting the printed circuit boards 407. In an embodiment, the buses 411 may be provided at or near the top of the printed circuit boards 407. Power and a ground outlet may be provided at or near the bottom of the printed circuit boards 409.

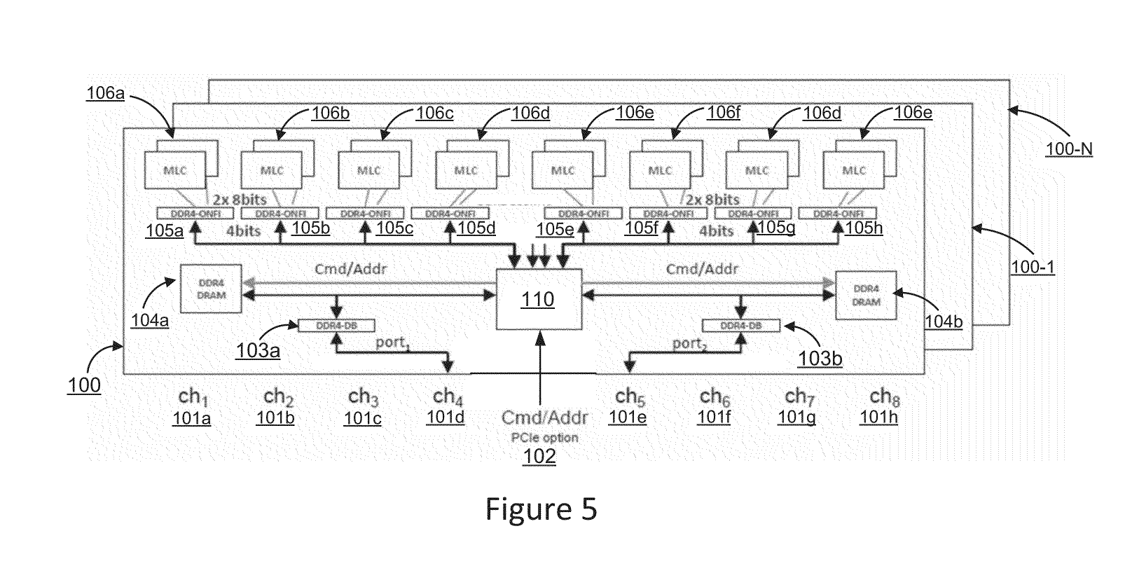

FIG. 5 is a block diagram depicting an exemplary DDR4-SSD dual-port DIMM and SSD Controller configuration scaled up by three connected printed circuit boards in accordance with embodiments of the present invention. FIG. 5 depicts multiple DIMM devices (e.g., 100, 100-1, 100-N, etc.) that include a number of components that are similar in functionality to DIMM device 100 (e.g., see FIG. 1). FIG. 5 illustrates how embodiments of the present invention can dynamically adjust the transmission frequency (e.g., doubling the frequency) of data between SSD Controller 110 and a set of DDR4-ONFI adapters (e.g., DDR4-ONFI adapters 105a through 105h) using pre-assigned channels of communications between SSD Controller 110 and the DDR4-ONFI adapters. For instance, as depicted in FIG. 5, each channel of communication between SSD Controller 110 and DDR4-ONFI adapters 105a through 105h can be adjusted based on the number of connected printed circuit board used. For example, using three or five connected printed circuit boards, each DDR4 channel can transmit 8 bit data to drive a set of DDR4-ONFI adapters 105 to split into two 8 bits ONFI channels for packed 3-PCB, and carry 4 bit data to drive a set of different DDR4-ONFI adapters 105 to split into two 8 bit channels for packed 5-PCB, thereby increasing pin fan-outs to the addition of each printed circuit board.

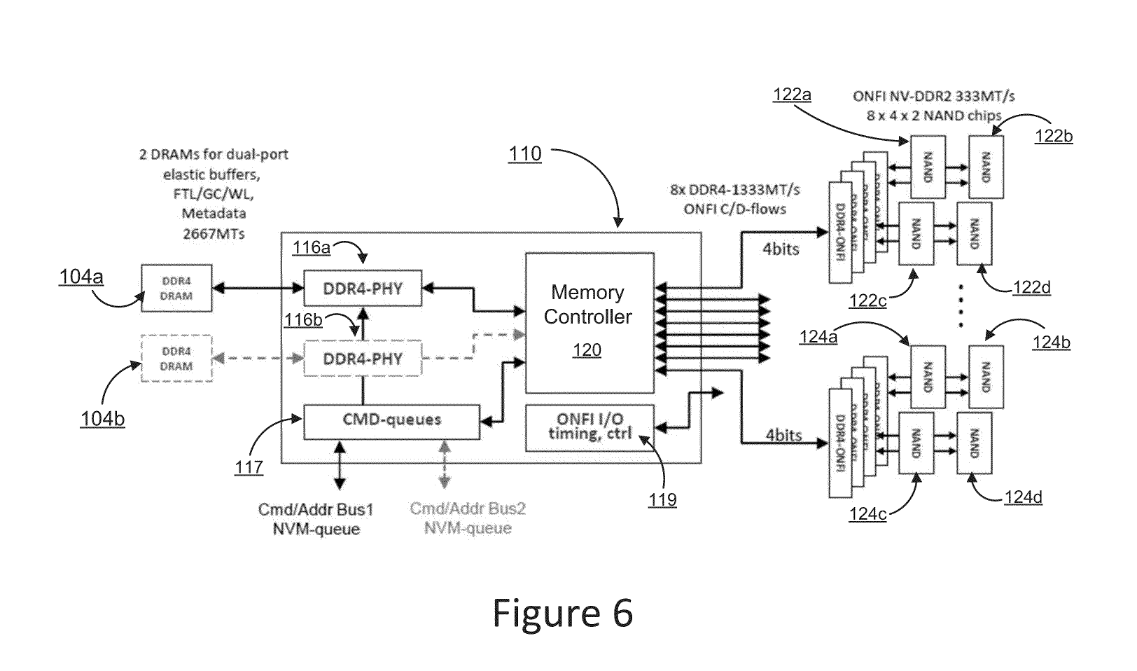

FIG. 6 is a block diagram of an exemplary SSD Controller adapted to scale multiple printed circuit boards with 4 bit DDR4 channels in accordance with embodiments of the present invention. FIG. 6 depicts SSD Controller 110, including a number of components that operate in a manner similar to functionality described in FIG. 2. As presented in FIG. 6, SSD Controller 110 can be configured to include an increased number of channels (depicted as bi-directional arrows) between SSD Controller 110 and a set of DDR4-ONFI adapters using pre-assigned channels of communications between SSD Controller 110 and DDR4-ONFI adapters (in 4 bit per DDR4 channel to split into two 8 bit ONFI-DDR2 channels). In this fashion, each channel of communication between SSD Controller 110 and a set of DDR4-ONFI adapters can be adjusted based on the number of connected printed circuit board used, thereby increasing pin life by the addition of each printed circuit board.

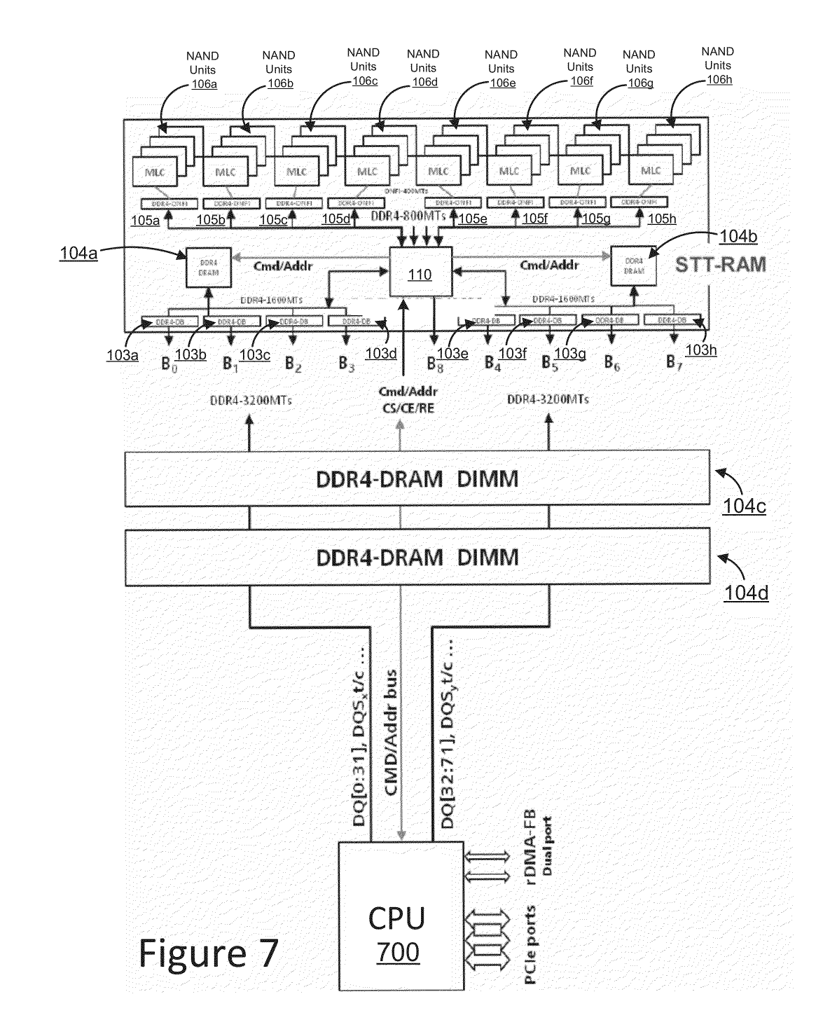

FIG. 7 is a block diagram of a DDR4 dual-port NVDIMM configuration in accordance with embodiments of the present invention. As described herein, embodiments of the present invention can use reconfigured DDR4-SSD controller 110 for conventional DDR4 72 bit data and cmd/address buses. As illustrated in FIG. 7, DIMM device 700 includes a number of components that appear similar and include functionality similar to that described in FIG. 1. DIMM device 700 includes 9 DDR4-DBs (e.g., DDR4-DB 103a through 103h) that support conventional 72 bit data bus (8 channels plus a parity channel) as described in FIG. 1. In one embodiment, a DDR3-STTRAM chip can be added for purposes of write caching and/or power-down data protections. Moreover, as depicted in FIG. 7, DIMM device 700 can be mixed with multiple DDR4-DRAM DIMMs (e.g., DDR4-DRAM DIMMs 104c, 104d, etc.) in conventional DDR4 motherboards. Furthermore, DIMM device 700 can receive input from a single host device (e.g., CPU 700) thereby, enabling SSD Controller 110 with firmware changes to operate in a mode that dedicates DDR4-DRAMs 104a and 104b to store commands received from CPU 700 for further processing by components of DIMM device 700. Meanwhile, the DDR4-DBs 103a-103h data butters are configured as 8 bit channel for motherboard plus two 4 bit channels that one linked to DDR4-DRAMs 104a or 104b and the another linked to DDR4-SSD controller to cut DRAM chip counts to half and leave more room for NAND flash chips for higher capacity and higher aggregated access bandwidths and IOPs (I/O Processing competence).

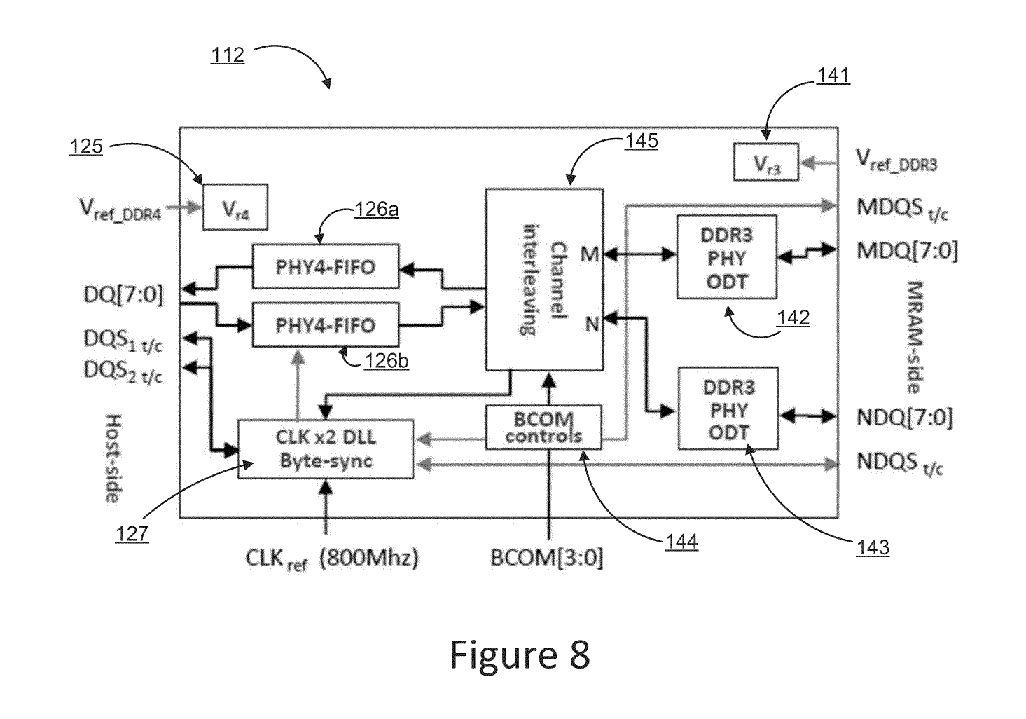

FIG. 8 is a block diagram of a DDR4-DDR3 speed-doubler configuration for building a DDR4-MRAM DIMM with slow DDR3-MRAM chips in accordance with embodiments of the present invention. FIG. 8 illustrates depicts host-side FIFO interfaces (e.g., PHY4-FIFO 126a and 126b), ODT interfaces (e.g., DDR3 PHY ODTs 142 and 143) which can be built in accordance with JESD79-4 specifications. As illustrated in the embodiment depicted in FIG. 8, DDR3 PHY ODTs 142 and 143 can be positioned on the MRAM-side. Furthermore, as depicted in channel interleaving 145, multiple 1666 MTs DDR3 channels can be interleaved to reach 3200 MTs DDR4 rate host access.

The V_{ref}_{_{—}}_{ddr4} and V_{ref}_{_{—}}_{ddr3} modules can generate threshold voltages for DDR4/DDR3 gating. DDR4-PHY interfaces can be trained and DLL locked with CLK_{ref} (800 MHz) for 3200 MTs strobes. Moreover, DDR3-PHY can be trained and DLL locked with CLK_{ref} and auto-terminated by DDR3 ODT. In this fashion, proper FIFOs can be configured to handle 8-bytes burst I/O elastic buffering then mix 2 slow channels. Furthermore, DQS_{1,2 t/c} DDR4 strobes and MDQS_{t/c}/NDQS_{t/c} DDR3 strobes can be synchronized to CLK_{ref}. BCOM[3:0] control port carries BCW according to JESD79-4 specifications.

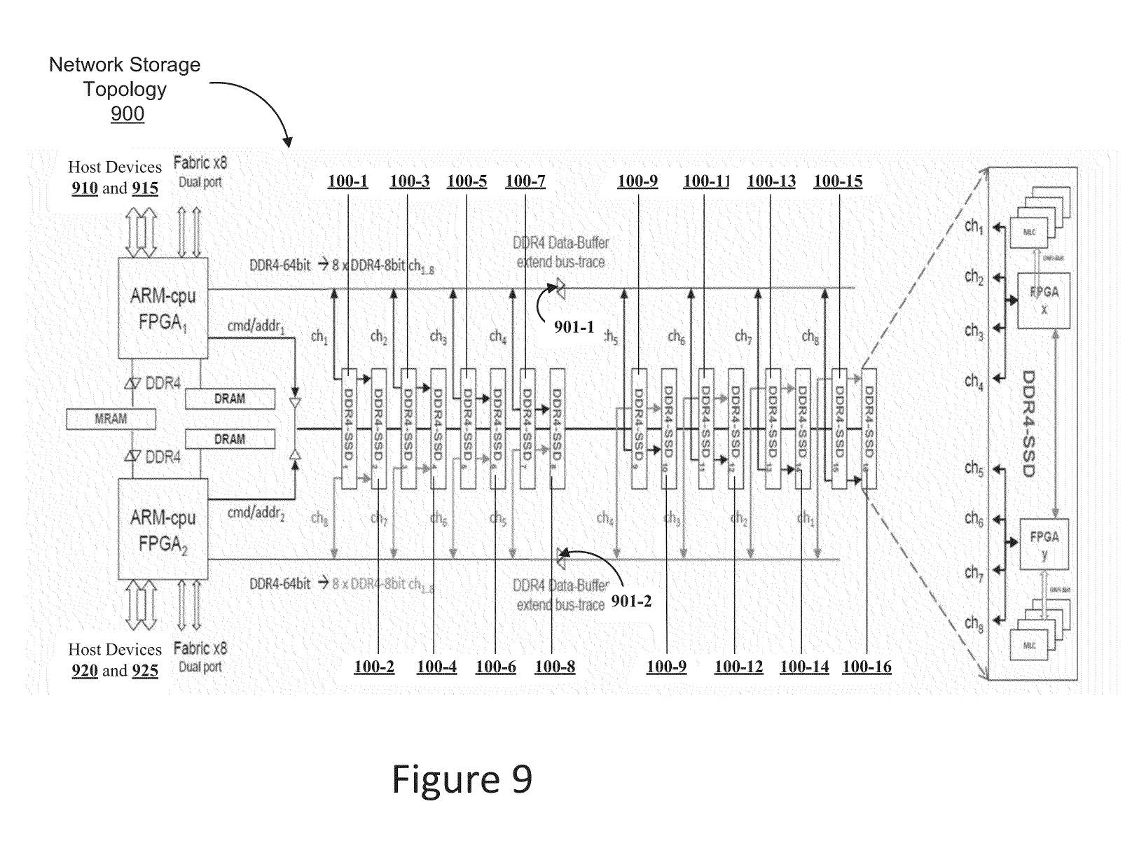

FIG. 9 depicts a network storage node topology 900 for distributed AFA clusters network storage in accordance with embodiments of the present invention. Topology 900 depicts 4 host devices (e.g., host devices 910, 915, 920, and 925) which share access to dual-port DDR4-SSD flash memory modules (e.g., DDR4-SSD dual-port DIMMs 100-1 through 100-16). According to an embodiment, each ARM64 CPU with FPGA is also cross-connected to all flash memory modules of another (separate) network storage node. The network storage node topology 900 includes a DDR4 spin wheel topology, where each CPU/FPGA is connected to all flash memory modules of two distinct network storage nodes. Due to the DDR4 spin wheel topology, for ‘S’ network storage nodes, there are ‘S+1’ processors. For certain board sizes, more CPU/FPGA nodes may be possible. While a spin wheel topology is depicted, other topologies are consistent with the spirit and scope of the present disclosure.

Furthermore, as depicted in FIG. 9, each DDR4-8 bit channel coupled to DDR4-SSD dual-port DIMMs 100-1 through 100-16 use a single byte (8-bits) of the DDR4-64 bit channel (e.g. 8 byte) to access two DDR4 DIMM loads for all of the DDR4-SSD DIMMs working at maximum speed rate and bus loads as ONFI-over-DDR4 interfaces. Thus, each DDR4-SSD dual-port DIMM can be connected to multiple hosts for simultaneous dual-access.

Furthermore, as depicted in FIG. 9, in one embodiment, DDR4 data-buffers (e.g., 901-1, 901-2) may be used to support more DIMMs, even with longer bus traces. For example, for certain printed circuit boards where a bus trace terminates before reaching every DIMM socket, data-buffers may be used to receive (and terminate) the signal from the memory controllers, and re-propagate the signal to the DIMMs that the bus trace does not reach. As presented FIG. 9, DIMM devices corresponding to channels 5-8 of the top memory controller and DIMM devices corresponding to channels 1-4 of the bottom memory controller may not be physically coupled to the bus trace in the underlying circuit board. Data accesses for read and write operations to those channels may be buffered and retransmitted by DDR4 data-buffers 901-1 and/or 901-2.

Furthermore, as depicted in FIG. 9, in one embodiment, DDR4 cmd/addr buses (e.g., 903-1, 903-2) can be modified as two 8 bit ONFI cmd/addr buses to drive/control total 16 DIMM loads, two from one CPU/FPGA and other two from another CPU/FPGA. The ONFI cmd/addr bus are working synchronously with ONFI data channels for burst writes (16 KB page) and burst reads (4 KB page) to 16 DDR4-SSD DIMM units 100-1˜100-16. Meanwhile, the NVME commands from four of host devices 910, 915, 920 and 925 can be inserted into the spin wheel of ONFI cmd/addr buses. The reads for status registers, pooling, and 4 KB bursts can always interrupt the write 16 KB bursts to lower flash read latency assuming all write data have been buffered in other NVM-DIMMs and committed to clients waiting for dedup decisions.

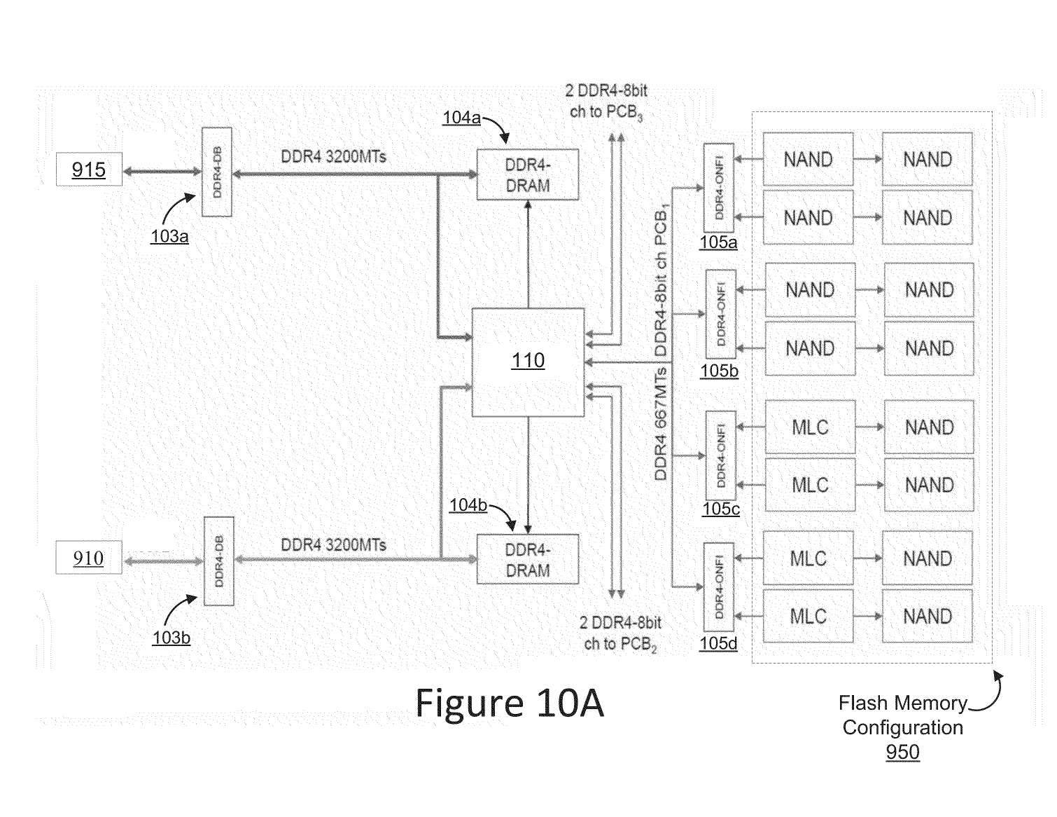

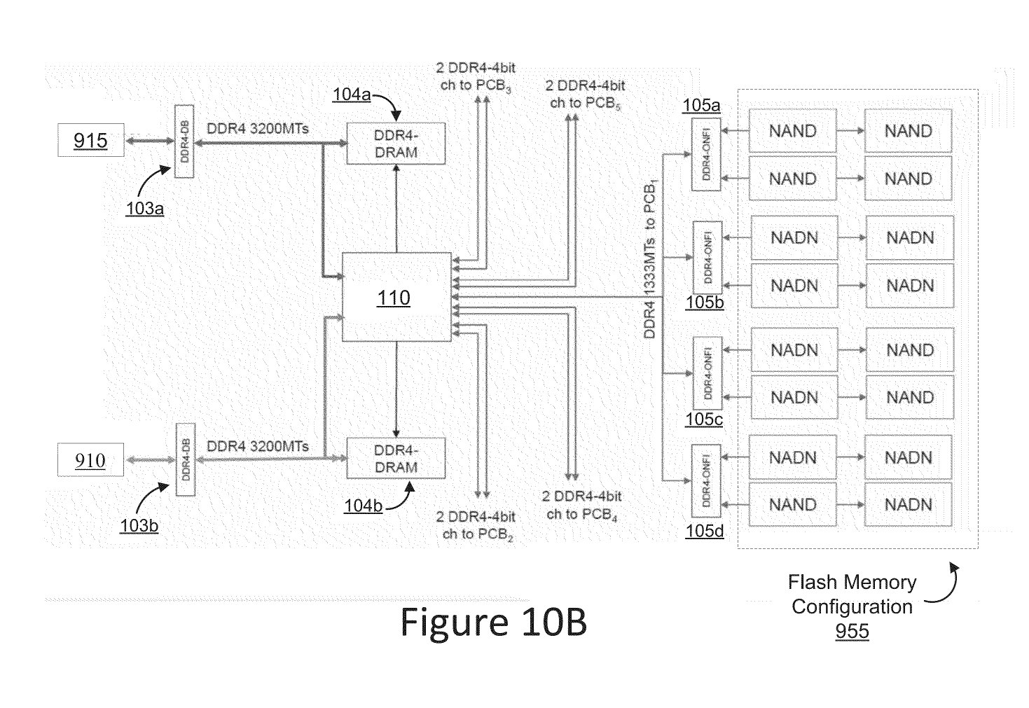

FIGS. 10A and 10B are block diagrams of an exemplary DDR4-SSD dual-port DIMM configuration supporting multiple host devices in accordance with embodiments of the present invention. As depicted in FIG. 10A, DDR4 DRAM 104a and 104b provide memory for host devices 910 and/or 915. DDR4 DRAM 104a and 104b enables host devices 910 and 915 to calculate a total amount of memory that each can provide when allocating a particular resource to a host device. In this fashion, host devices 910 and 915 can read data from and/or write data to DDR4 DRAM 104a and/or 104b. As described herein, SSD Controller 110 can determine whether a particular DDR4 DRAM (e.g., DDR4 DRAM 104a) is experiencing higher latency than another DDR4 DRAM (e.g., DDR4 DRAM 104b).

Thus, when responding to a command from either host device 910 or 915 to perform a procedure, SSD Controller 110 can communicate the instructions sent by the requesting host device to the DDR4 DRAM that is available to perform the requested procedure where it can then be store for processing. In this manner, DDR4 DRAM 104a and 104b act as separate elastic buffers that are capable of buffering data received DDR4-DBs 103a and 103b. Moreover, in this fashion, the two paths can use active-passive (“standby”) or active-active modes to increase the reliability and availability of the storage systems on DIMM device 100.

Furthermore, FIG. 10A depicts how SSD Controller 110 can perform bus adaption procedures (via memory controller 120) which include interpreting random access instructions (e.g., instructions concerning DDR4-DRAM procedures) as well as page (or block) access instructions (e.g., instruction concerning NAND processing procedures). As illustrated in FIG. 10A, SSD Controller 110 can establish multiple channels of communications for a set of flash memory (e.g., flash memory configuration 950) through their corresponding DDR4-ONFI adapters (e.g., DDR4-ONFI adapters 105a through 105d). For instance, each channel of communication can transmit 8 bits of data which can drive 4 different DDR4-ONFI adapters. As such, a DDR4-ONFI adapter can drive at least two NAND chips. There are two more DDR4-8 bit channels linked to PCB2 106 and other two DDR4-8 bit channels to PCB3 107 from SSD Controller 110 to scale-up the packed 3-PCB DIMM unit. FIG. 10B illustrates another embodiment in which SSD Controller 110 can perform bus adaption procedures.

As illustrated in FIG. 10B, SSD Controller 110 can establish multiple channels of communications for a set of flash memory (e.g., flash memory configuration 955) through their corresponding DDR4-ONFI adapters (e.g., DDR4-ONFI adapters 105a through 105d). For instance, each channel of communication between SSD Controller 110 and DDR4-ONFI adapters 105a through 105d can be adjusted based on the number of connected printed circuit board (PCB) used. For example, using 5 connected printed circuit boards, each channel can be adjust to transmit 4 bits of data to drive a set of different DDR4-ONFI adapters, thereby increasing SSD Controller 110 pin fan-out capacity by the addition of each printed circuit board as packed 5-PCB DIMM unit.

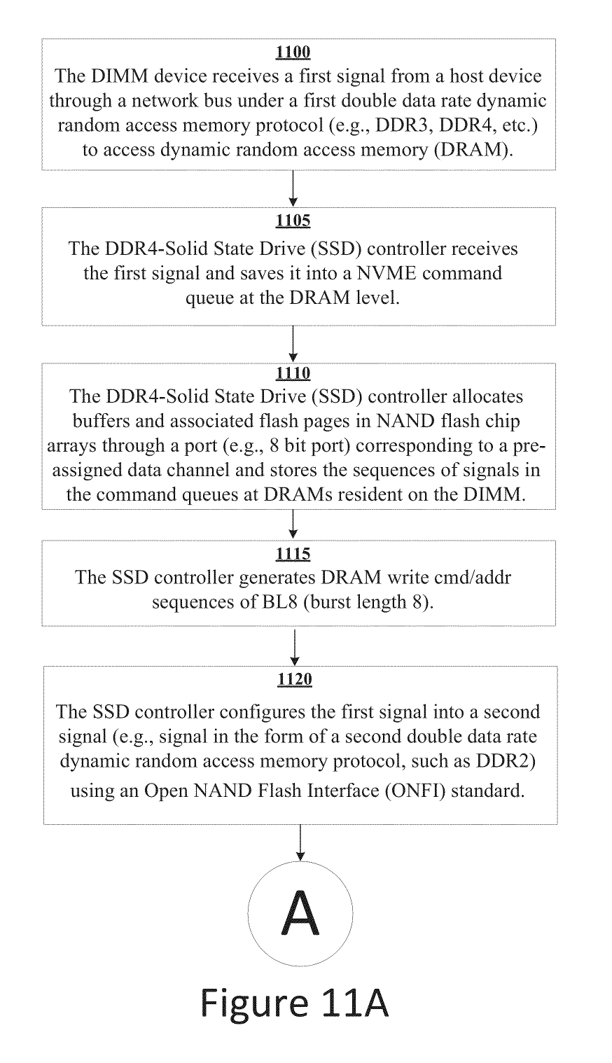

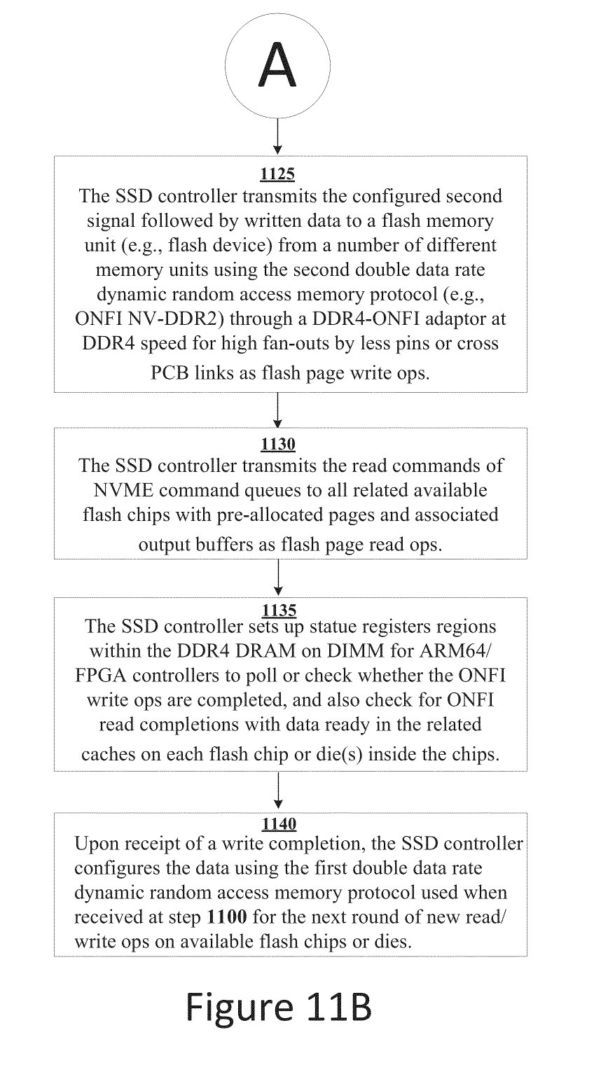

FIG. 11A is a flowchart of first portion of an exemplary computer-implemented method for performing data access request in a network storage system in accordance with embodiments of the present invention.

As shown in FIG. 11A, at step 1100, the DIMM device receives a first signal from a host device through a network bus under a first double data rate dynamic random access memory protocol (e.g., DDR3, DDR4, etc.) to access dynamic random access memory (DRAM). The first signal includes instructions to access DRAM resident on the DIMM device. For example, the signal may be a NVME read command with flash LBA (logic block address) and DRAM address to buffer the fetched flash page, or a NVME write command with DRAM address that buffer the input data and flash LBA to save the data in NAND chip, thru one of 8 bit ONFI Cmd/Addr buses.

At step 1105, the DDR4-Solid State Drive (SSD) controller receives the first signal and saves it into a NVME command queue at the DRAM level.

As step 1110, the DDR4-Solid State Drive (SSD) controller allocates buffers and associated flash pages in NAND flash chip arrays through a port (e.g., 8 bit port) corresponding to a pre-assigned data channel and stores the sequences of signals in the command queues at DRAMs resident on the DIMM. In one embodiment, the SSD controller can select the data buffers to store the signals or/and consequence data bursts based on detected DRAM traffic conditions concerning each data buffer.

At step 1115, the SSD controller generates DRAM write cmd/addr sequences of BL8 (burst length 8). These sequences (e.g., writes) can be generated using pre-allocated write buffers. In this fashion, a host can perform DMA/RDMA write operations using 4 KB or 16 KB data bursts into DRAMs with synchronized cmd/addr sequences by the SSD controller. In one embodiment, SSD controller can pack four 4 KB into a 16 KB page.

At step 1120, the SSD controller configures the first signal into a second signal (e.g., signal in the form of a second double data rate dynamic random access memory protocol, such as DDR2) using an Open NAND Flash Interface (ONFI) standard. The ONFI-over-DDR4 interface can modify an ONFI NV-DDR2 Cmd/Addr/data stream by splitting one 8 bit channel into ONFI Cmd/Addr bus to control 8 of DDR4-SSD DIMMs and one 8 bit ONFI data channel to stream long burst data transfers (reads or writes) for optimizing bus utilizations.

As shown in FIG. 11B, at step 1125, the SSD controller transmits the configured second signal followed by written data (e.g., 16 KB) to a flash memory unit (e.g., flash device) from a number of different memory units using the second double data rate dynamic random access memory protocol (e.g., ONFI NV-DDR2) through a DDR4-ONFI adaptor at DDR4 speed for high fan-outs by less pins or cross PCB links as flash page write ops.

At step 1130, the SSD controller transmits the read commands of NVME command queues to all related available flash chips with pre-allocated pages and associated output buffers as flash page read ops. All related DDR4-ONFI adaptors thru the cmd/addr/data streaming paths are carrying out the DDR4-to-DDR2 signal level and data rate adaptation and termination and/or retransmission functions.

At step 1135, the SSD controller sets up statue registers regions within the DDR4 DRAM on DIMM for ARM64/FPGA controllers to poll or check whether the ONFI write ops are completed, and also check for ONFI read completions with data ready in the related caches on each flash chip or die(s) inside the chips. In one embodiment, SSD controller can also send hardware interrupts to the unified memory interface at ARM64/FPGA controllers via the 8 bit ONFI cmd/addr bus (modified conventional DDR4 cmd/addr bus to be bi-directional bus). Upon ARM64/FPGA controller polling a read completion, ARM64/FPGA can interrupt the related host device for DMA read directly from the DRAM on DIMM, or will setup RDMA-engine in the ARM64/FPGA controller to RDMA write data packet (4 KB or 8 KB) to the assigned memory space in the host device by reading the DDR4-SSD DIMM associated read buffer. The SSD controller can generate the DRAM read cmd/address sequences to synchronously support this RDMA read burst (in 64 B or 256 B size).

At step 1140, upon receipt of a write completion, the SSD controller configures the data using the first double data rate dynamic random access memory protocol used when received at step 1100 for the next round of new read/write ops on available flash chips or dies. In one embodiment, the SSD controller can interrupt the ARM64/FPGA controller with relayed write-completion info in corresponding status registers; upon receipt of a read ready, the SSD controller will fetch the cached page in related flash chip and write to them to the pre-allocated output buffer in DRAM, then interrupt the ARM64/FPGA controller with relayed read-completion info.

Although exemplary embodiments of the present disclosure are described above with reference to the accompanying drawings, those skilled in the art will understand that the present disclosure may be implemented in various ways without changing the necessary features or the spirit of the present disclosure. The scope of the present disclosure will be interpreted by the claims below, and it will be construed that all techniques within the scope equivalent thereto belong to the scope of the present disclosure.

According to an embodiment, the techniques described herein are implemented by one or more special-purpose computing devices. The special-purpose computing devices may be hard-wired to perform the techniques, or may include digital electronic devices such as one or more application-specific integrated circuits (ASICs) or field programmable gate arrays (FPGAs) that are persistently programmed to perform the techniques, or may include one or more general purpose hardware processors programmed to perform the techniques pursuant to program instructions in firmware, memory, other storage, or a combination. Such special-purpose computing devices may also combine custom hard-wired logic, ASICs, or FPGAs with custom programming to accomplish the techniques. The special-purpose computing devices may be database servers, storage devices, desktop computer systems, portable computer systems, handheld devices, networking devices or any other device that incorporates hard-wired and/or program logic to implement the techniques.

In the foregoing detailed description of embodiments of the present invention, numerous specific details have been set forth in order to provide a thorough understanding of the present invention. However, it will be recognized by one of ordinary skill in the art that the present invention is able to be practiced without these specific details. In other instances, well-known methods, procedures, components, and circuits have not been described in detail so as not to unnecessarily obscure aspects of the embodiments of the present invention. Although a method is able to be depicted as a sequence of numbered steps for clarity, the numbering does not necessarily dictate the order of the steps. It should be understood that some of the steps may be skipped, performed in parallel, or performed without the requirement of maintaining a strict order of sequence. The drawings showing embodiments of the invention are semi-diagrammatic and not to scale and, particularly, some of the dimensions are for the clarity of presentation and are shown exaggerated in the drawing Figures. Similarly, although the views in the drawings for the ease of description generally show similar orientations, this depiction in the Figures is arbitrary for the most part.

Embodiments according to the present disclosure are thus described. While the present disclosure has been described in particular embodiments, it is intended that the invention shall be limited only to the extent required by the appended claims and the rules and principles of applicable law.

What is claimed is:

1. An apparatus comprising:
an Open NAND Flash Interface (ONFI) communication interface for communicating with a plurality of flash memory devices; and
a Solid State Drive (SSD) processor coupled to said communication interface and configured to:
receive a first signal from a first host device corresponding to a first double data rate dynamic random access memory (DDR) protocol to access dynamic random access memory (DRAM);
store said first signal upon receipt in a data buffer of a plurality of data buffers resident on said apparatus;
convert said first signal into a second signal using an Open NAND Flash Interface (ONFI) standard;
transmit said configured second signal to one of said plurality of flash memory devices corresponding to a second double data rate dynamic random access memory (DDR) protocol, wherein said second DDR protocol is different from said first DDR protocol; and
receive data from said flash memory device, wherein said data is converted into signals corresponding to said first DDR4 protocol for communication to said first host device.

2. The apparatus of claim 1, wherein said first double data rate dynamic random access memory (DDR) protocol is a DDR4 protocol and said second double data rate dynamic random access memory (DDR) protocol is a DDR2 protocol.

3. The apparatus of claim 1, wherein said processor is operable to receive said first signal through a port corresponding to a pre-programmed channel.

4. The apparatus of claim 1, wherein said processor is operable to receive a third signal from a second host device under said first double data rate dynamic random access memory (DDR) protocol to access dynamic random access memory (DRAM).

5. The apparatus of claim 4, wherein said processor is operable to select one data buffer of said plurality of data buffers for storing said third signal based on a network traffic condition.

6. The apparatus of claim 1, wherein said processor uses a set of pre-programmed channels to transmit data to said plurality of flash memory devices at a first bit rate.

7. The apparatus of claim 6, wherein said first bit rate is adjusted based on a number of pre-programmed channels used by said processor to transmit said data to said plurality of flash memory devices.

8. A method of accessing memory from a dual in-line memory module (DIMM), said method comprising:
receiving a first signal from a first host device under a first double data rate dynamic random access memory (DDR) protocol to access dynamic random access memory (DRAM), wherein said first signal comprises instructions to access DRAM resident on said DIMM;
storing said first signal upon receipt in one data buffer of a plurality of data buffers resident on said DIMM;
configuring said first signal into a second signal using an Open NAND Flash Interface (ONFI) standard;
transmitting said configured second signal to one memory unit of a plurality of memory units under a second double data rate dynamic random access memory (DDR) protocol, wherein said second double data rate dynamic random access memory (DDR) protocol, wherein said second DDR protocol is different from said first DDR protocol; and
receiving data from said memory unit under said second double data rate dynamic random access memory (DDR) protocol, wherein said data is configured upon receipt by said SSD controller using said first double data rate dynamic random access memory (DDR) protocol for transmission to said first host device.

9. The method of claim 8, wherein said first double data rate dynamic random access memory (DDR) protocol is a DDR4 protocol and said second double data rate dynamic random access memory (DDR) protocol is a DDR2 protocol.

10. The method of claim 8, wherein said configuring said first signal further comprises using a Solid State Drive (SSD) controller to perform configuration procedures.

11. The method of claim 8, wherein said receiving further comprises receiving said first signal through a port corresponding to a pre-programmed channel.

12. The method of claim 8, wherein said storing further comprises:
receiving a third signal from a second host device under said first double data rate dynamic random access memory (DDR) protocol to access dynamic random access memory (DRAM), wherein said third signal comprises instructions to access DRAM resident on said DIMM;
selecting one data buffer of said plurality of data buffers for storing said third signal based on a network traffic condition associated with said DIMM.

13. The method of claim 8, wherein said transmitting said configured second signal further comprises using a set of pre-programmed channels to transmit data to said plurality of memory units at a first bit rate.

14. The method of claim 13, wherein said first bit rate is adjusted based on a number of pre-programmed channels used to transmit said data to said plurality of memory units.

15. A SSD dual-port dual in-line memory module (DIMM), comprising:
a Solid State Drive (SSD) controller;
a Open NAND Flash Interface (ONFI) adapter communicatively coupled to said SSD controller; and
a plurality of NAND chips communicatively coupled to said ONFI adapter, wherein the NAND chips are controlled by said SSD controller.

16. The SSD dual-port DIMM of claim 15, wherein said DDR4-SSD controller is communicatively coupled to a plurality of 8-bit ports configured for receiving signals from a host device.

17. The SSD dual-port DIMM of claim 15, wherein said DDR4-SSD controller is configured to use an active-passive dual-access mode for receiving signals from a plurality of host devices.

18. The SSD dual-port DIMM of claim 15, wherein only 1 port is used in said active-passive dual-access mode.

19. The SSD dual-port DIMM of claim 15, wherein only 1 byte is used in the dual-access mode.

20. The SSD dual-port DIMM of claim 15, wherein the ONFI adapter comprises a CLK-DLL configured to synchronize DQS and DQS_M/N data-strobe pairs for proper timing and phase and 2 Vrefs for DDR4 and DDR2 voltages and terminations.
